(19) United States
(12) Patent Application Publication
(10) Pub. No.: US 2012/0015215 A1
(43) Pub. Date: Jan. 19, 2012

(54) RECHARGEABLE BATTERY PACK AND MANUFACTURING METHOD OF THE SAME

(75) Inventor: Young-Jun Kim, Yongin-si (KR)

(73) Assignee: Samsung SDI Co., Ltd., Yongin-si (KR)

(21) Appl. No.: 12/986,689

(22) Filed: Jan. 7, 2011

(30) Foreign Application Priority Data
Jul. 15, 2010 (KR) 2010-0068509

(51) Int. Cl. H01M 10/42; G01R 31/36

(52) U.S. Cl. 429/7; 29/593

(57) ABSTRACT

A rechargeable battery pack comprises a cell pack comprising unit cells formed with rechargeable batteries; a protection circuit module; a temperature sensor attached to a unit cell having the fastest speed of temperature increase among the unit cells, and connected to the protection circuit module. A method includes a classifying step including selecting unit cells within a predetermined range of voltage-current characteristic and classifying the unit cells by a speed of temperature increase; a cell packing step connecting the unit cells, disposing a unit cell having the fastest speed of temperature increase to a position where a temperature sensor is connected and then connecting the classified unit cells to form a cell pack; a connecting step for installing a protection circuit module to a position where the temperature sensor is connected and then connecting the temperature sensor with the unit cell and the protection circuit module with the temperature sensor.

### CLAIM OF PRIORITY

This application makes reference to, incorporates the same herein, and claims all benefits accruing under 35 U.S.C. §119 from an application for RECHARGEABLE BATTERY PACK AND METHOD FOR MANUFACTURING THE SAME earlier filed in the Korean intellectual Property Office on Jul. 15, 2010 and there duly assigned Serial No. 10-2010-0068509.

### BACKGROUND OF THE INVENTION

1. Field of the Invention

The following description relates to a rechargeable battery pack having a protecting function for an increase in temperature and a method for manufacturing the rechargeable battery pack, and more particularly, to a rechargeable battery pack having a cell pack, a protection circuit module and a temperature sensor and a method for manufacturing the same.

2. Description of the Related Art

Needs for a rechargeable battery pack as an energy source have been increased along with developments and requirements for mobile devices. The rechargeable battery pack may be used as a unit cell or a cell pack in which unit cells are electrically connected to each other.

For example, the rechargeable battery pack includes a cell pack in which a plurality of unit cells are coupled in series or in parallel, and a protection circuit module (PCM) protecting the cell pack by mounting protection circuit parts. The protection circuit module is formed by mounting protection circuit parts to protect the cell pack against overcharge, overdischarge, overcurrent, and short circuit.

Also, the protection circuit module electrically blocks the cell pack when the temperature of the cell pack is increased by overcurrent in order to prevent a charge and discharge operation on the cell pack. Therefore, the protection circuit module has a temperature protecting function for preventing the cell pack against an increase in temperature. For this purpose, the rechargeable battery pack includes one temperature sensor (thermistor) attached to one unit cell among the cell pack. The thermistor is electrically connected to the protection circuit module. Accordingly, the protection circuit module electrically intercepts the circuit amount of the cell pack according to the temperature detected from the thermistor.

In the cell pack, the speed of the temperature increase for each unit cell is different. Accordingly, when the thermistor is not installed to a unit cell having the fastest speed of the temperature increase among other unit cells, the temperature protection functioned by the protection circuit module may not be operated until the cell pack is damaged. Accordingly, the temperature protecting function of the cell pack may not be efficiently operated.

The above information described in this background section is only to enhance the comprehension of the principles of the present invention and therefore it may contain information that does not form prior art that is already known to a person of ordinary skill in the art.

### SUMMARY OF THE INVENTION

The following described technology is made in an effort to provide a rechargeable battery pack and a method for manufacturing the rechargeable battery pack. The following described technology is made in an effort to provide a protection circuit module electrically connected on a unit cell having the fastest speed of temperature increase among other unit cells in a cell pack to normally operate a temperature protecting function to the cell pack.

A rechargeable battery pack according to an exemplary embodiment includes: a cell pack including unit cells formed with rechargeable batteries; a protection circuit module electrically protecting the cell pack; and a temperature sensor attached to a unit cell having the fastest speed of temperature increase among the unit cells, and electrically connected to the protection circuit module.

The temperature sensor may be formed with a thermistor.

The temperature sensor may be attached to a unit cell having the lowest internal resistance among the unit cells.

The temperature sensor may be attached to a unit cell having the largest output current amount among the unit cells.

The temperature sensor may be attached to one side of anode terminal in a unit cell having the fastest speed of temperature increase.

The unit cell may be formed of either a cylindrical rechargeable batteries and an angular rechargeable batteries.

The temperature sensor may be attached to a curved surface a can of a cylindrical rechargeable battery.

The temperature sensor may be attached to a flat surface a can of an angular rechargeable battery.

A method for manufacturing a rechargeable battery pack according to an exemplary embodiment includes: a classifying step including selecting unit cells within a predetermined range of voltage-current characteristic and classifying unit cells according to a speed of temperature increase, and the unit cells are formed of rechargeable batteries; a cell packing step for connecting the unit cells, disposing a unit cell having the fastest speed of temperature increase to a position where a temperature sensor is connected and then electrically connecting the classified unit cells to form a cell pack; and a connecting step for installing a protection circuit module to a position where the temperature sensor is connected and then connecting the temperature sensor with the unit cell having the fastest speed of temperature increase in a terminal of the cell pack and the protection circuit module with the temperature sensor.

The classifying step may classify the unit cells according to internal resistance.

The classifying step may classify the unit cells according to output current amounts.

The connecting step may attach the temperature sensor to a side of anode terminal of the unit cell having the fastest speed of temperature increase.

According to an exemplary embodiment, the temperature sensor is attached to the unit cell having the fastest speed of temperature increase among the unit cells in a cell pack such that the protection circuit module may control the cell pack through detected signals of temperature. Accordingly, the temperature protection functioned by a protection circuit module on the cell pack may be actively executed. Therefore, the cell pack of the rechargeable battery pack is efficiently protected against overcharge, overdischarge, overcurrent, and short circuit by attaching the temperature sensor on the unit cell having the fastest speed of the temperature increase.

### BRIEF DESCRIPTION OF THE DRAWINGS

A more complete appreciation of the present invention, and many of the attendant advantages thereof, will be readily apparent as the present invention becomes better understood by reference to the following detailed description when considered in conjunction with the accompanying drawings, in which like reference symbols indicate the same or similar components, wherein:

FIG. 1 is a perspective view of a rechargeable battery pack constructed as a first exemplary embodiment of present invention.

FIG. 2 is a cross-sectional view of unit cell 1 (i.e. a rechargeable battery) applied to the rechargeable battery pack of FIG. 1.

FIG. 3 is part of a cross-sectional view taken along line of FIG. 1.

FIG. 4 is a perspective view of a rechargeable battery pack constructed as a second exemplary embodiment of present invention.

FIG. 5 is a cross-sectional view of unit cell 41 (i.e. a rechargeable battery) applied to the rechargeable battery pack of FIG. 4.

FIG. 6 is part of a cross-sectional view taken along line VI-VI′ of FIG. 4.

FIG. 7 is a flowchart illustrating a method for manufacturing a rechargeable battery pack constructed as an exemplary embodiment of present invention.

### DETAILED DESCRIPTION OF THE INVENTION

The general inventive concept is described more fully below with reference to the accompanying drawings, in which exemplary embodiments of the present invention are shown. As those skilled in the art would realize, the described embodiments may be modified in various different ways, all without departing from the spirit or scope of the present invention. The present invention should not be construed as being limited to the embodiments. Accordingly, the drawings and description are to be regarded as illustrative in nature to explain aspects of the present invention and not restrictive. Like reference numerals in the drawings designate like elements throughout the specification, and thus their description have not been repeated.

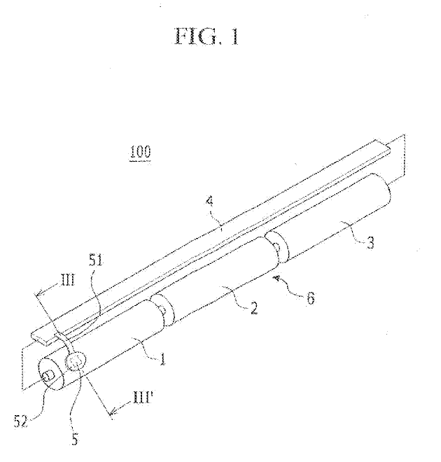

FIG. 1 is a perspective view of a rechargeable battery pack constructed as a first exemplary embodiment of present invention. As shown in FIG. 1, a rechargeable battery pack 100 includes a cell pack 6. The cell pack 6 includes first, second, and third unit cells 1, 2, and 3. The first, second, and third unit cells 1, 2, and 3 are connected in series. Each of the first, second, and third unit cells 1, 2, and 3 is made of a rechargeable battery. A protection circuit module 4 (PCM) is connected to a terminal of the cell pack 6 and electrically protects the cell pack 6. A temperature sensor 5 is attached to the first unit cell 1 and is electrically connected to the protection circuit module 4.

For convenience, the first exemplary embodiment of the present invention provides the cell pack 6 and the cell pack 6 includes three unit cells, that is, the first, second, and third unit cells 1, 2, and 3: The first, second, and third unit cells 1, 2, and 3 are connected in series. Although not shown, the cell pack 6 may be formed by connecting two or more unit cells in series or in parallel.

In addition, although not showing in FIG. 1, when forming the cell pack 6, a connection tab is respectively applied between the first and second unit cells 1 and 2, and between the second and third unit cells 2 and 3. The connection tab connects the first, second, and third unit cells 1, 2, and 3 and makes the first, second, and third unit cells 1, 2, and 3 neighbor each other. The connection tab may also be electrically connected to the protection circuit module 4.

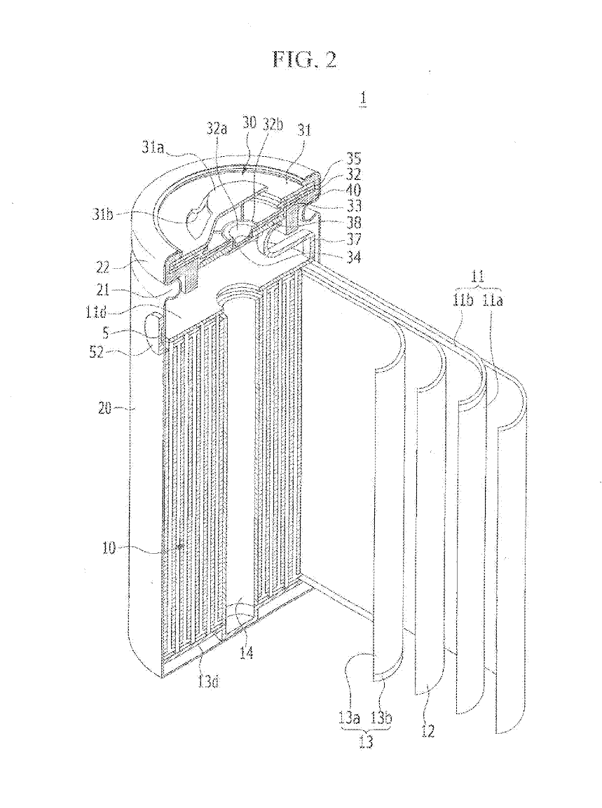

The structure of the first, second, and third unit cells 1, 2, and 3 formed with rechargeable batteries is the same. In other words, each of the first, second, and third unit cells 1, 2, and 3 is a rechargeable battery with same structure. FIG. 2 is a cross-sectional view of the unit cell 1 (i.e. a rechargeable battery) applied to the rechargeable battery pack of FIG. 1. As shown in FIG. 2, the first unit cell 1 includes an electrode assembly 10, a can 20, and a cap assembly 30. In the electrode assembly 10, a charge and a discharge are operated. The can 20 encompasses the electrode assembly 10. The cap assembly 30 is combined to the can 20 and electrically connected to the electrode assembly 10.

The electrode assembly 10 includes a first electrode 11 (hereinafter, refers to as an “anode”), a separator 12, and a second electrode 13 (hereinafter, refers to as a “cathode”). The anode 11, the separator 12, and the cathode 13 are sequentially deposited and disposed. The electrode assembly 10 is formed by spiral-wounding the anode 11, the separator 12 and the cathode 13. The separator 12 is disposed between the anode 11 and the cathode 13 as an insulator with a jelly roll shape. As one example, the electrode assembly 10 is formed as a cylinder in FIG. 2. A sector pin 14 is disposed at the center of the cylindrical electrode assembly 10. The sector pin 14 maintains the electrode assembly 10 in the cylinder shape.

The anode 11 and the cathode 13 include current collectors and are formed with a thin metal plate. The anode 11 and the cathode 13 also include coated regions 11 a, 13a and uncoated regions 11b, 13b, respectively. If the uncoated region 11b is formed on the top area of the cylindrical electrode assembly 10, the uncoated region 13b is formed on the bottom of the cylindrical electrode assembly 10. Therefore, the uncoated regions 11b and 13b are disposed at the opposite side. An active material is coated on both surfaces of the current collector on the coated regions 11a and 13a, and an active material is not coated on the uncoated regions 11b and 13b. In a jelly roll shape of the electrode assembly 10, an anode collecting plate 11d is connected to the uncoated region 11b of the anode 11 on one side of the electrode assembly 10, and a cathode collecting plate 13d is connected to the uncoated region 13b of the cathode 13 on the other side of the electrode assembly 10.

The can 20 has an opening at one side to allow the cylinder shaped electrode assembly 10 to be inserted therein. The can 20 encompasses the electrode assembly 10 and an electrolyte solution inside. The can 20 is connected to the cathode collecting plate 13d so as to serve as a cathode terminal in the first unit cell 1. The can 20 may be made of a conductive metal such as aluminum, an aluminum alloy, or nickel-plated steel.

The cap assembly 30 includes a cap plate 31, a positive temperature coefficient (PTC) element 35, a vent plate 32, an insulating substrate 33, a middle plate 38, and a sub-plate 34, which are sequentially disposed from the outer side to the inner side of the can 20. The cap assembly 30 is coupled to the opening of the can 20 by interposing a gasket 40 therebetween to close and seal the can 20. The cap assembly 30 also includes a current interruption unit, and the cap assembly 30 is electrically connected to the electrode assembly 10 via the current interruption unit.

The cap plate 31 is finally connected to the anode collecting plate 11d. The anode collecting plate 11d operates as an anode terminal in the first unit cell 1. The cap plate 31 has a protruding portion 31a protruded outside of the can 20. An exhaust port 31b is opened at the side of the protruding portion 31a.

Substantially, the current interruption unit is formed with the vent plate 32, the sub-plate 34, and a connection thereof. For example, the connection of the current interruption unit may be formed by welding of the vent plate 32 and the sub-plate 34. The vent plate 32 formed on one side of the current interruption unit is placed at the inner side of the cap plate 31 in order to electrically connect to the sub-plate 34 formed on the other side of the current interruption unit. In addition, the vent plate 32 includes a vent 32a and a notch 32b. The vent 32a is deformed in a predetermined pressure condition such that a gas inside the first unit cell 1 is discharged and the electrical connection along with the sub-plate 34 is interrupted.

When the current interruption unit is operated, that is, when the connection of the vent plate 32 and the sub-plate 34 is disconnected by deforming the vent 32a, the electrode assembly 10 and the cap plate 31 are electrically disconnected. For example, the vent 32a is protruded from the vent plate 32 toward the inside of the can 20. The notch 32h guide the deformation of the vent 32a near the vent 32a. When the gas is generated in the can 20 and the internal pressure of the first unit cell 1 is increased by the gas, the notch 32b is firstly damaged to discharge the gas such that an explosion of the first unit cell 1 may be prevented.

The positive temperature coefficient element 35 is placed between the cap plate 31 and the vent plate 32, and thereby the current flowing between the cap plate 31 and the vent plate 32 may be controlled by the inner temperature inside of the first unit cell 1. When the inner temperature exceeds a predetermined temperature, the electrical resistance of the positive temperature coefficient element 35 is increased approximately to infinity. Therefore, the positive temperature coefficient element 35 may interrupt the flow of the charging or discharging current between the cap plate 31 and the vent plate 32.

A charge or a discharge driving appears as a temperature increase in the unit cell, for example, the first unit cell 1. The inner temperature increases according to the charge or discharge driving. The electrical resistance of the positive temperature coefficient element 35 is changed according to the inner temperature. Accordingly, the positive temperature coefficient element 35 has the greatest effect on the determination of the internal resistance among the other constituent elements of the first unit cell 1. That is, the electrical resistance of the positive temperature coefficient element 35 increases as the inner temperature increases, and thereby the internal resistance of the first unit cell 1 increases. In other words, the inner temperature increases as the internal resistance increases, and thereby the outer temperature of the first unit cell 1 increases. That is, each internal resistance of the first, second, and third unit cells 1, 2, and 3 in the cell pack 6 is measured such that the speed of the relative temperature increase of the first, second, and third unit cells 1, 2, and 3 may be predicted. The speed of the inner temperature increase increases when the internal resistance is small.

The sub-plate 34 faces the vent plate 32 with respect to the insulating substrate 33, and is electrically connected to the vent 32a. The middle plate 38 is disposed between the insulating substrate 33 and the sub-plate 34. The vent 32a protruded through penetration holes of the insulating substrate 33 and the middle plate 38, and is connected to the sub-plate 34. Accordingly, part of the middle plate 38 is electrically connected to the vent plate 32 through the sub-plate 34 and the vent 32a, and part of the middle plate 38 is connected to the anode collecting plate 11d through a connection member 37. Resultantly, the anode collecting plate 11d is electrically connected to the cap plate 31 through the connection member 37, the middle plate 38, the sub-plate 34, the vent 32a, the vent plate 32, and the positive temperature coefficient element 35.

The can 20 has a beading portion 21 and a clamping portion 22 on the side of the opening. The cap assembly 30 is coupled to the opening of the can 20, and is fixed to the can 20 by a clamping process through the beading portion 21 and the clamping portion 22 to complete the first unit cell 1.

Again as shown in FIG. 1, the protection circuit module 4 is formed to electrically protect the cell pack 6, and is connected to the terminal of the cell pack 6. For example, the protection circuit module 4 is formed by mounting a protection circuit parts to a circuit board, and protects the cell pack 6 from overcharge, overdischarge, overcurrent, and short circuit.

Again as shown in FIG. 1 and FIG. 2, the temperature sensor 5 is attached to the unit cell 1, and the unit cell 1 has the fastest speed of the temperature increase among the first, second, and third unit cells 1, 2, and 3. For example, the first exemplary embodiment shows that the first unit cell 1 has a faster speed of the temperature increase than the second and third unit cells 2 and 3.

For example, the speed of the temperature increase of the first, second, and third unit cells 1, 2, and 3 may be determined by the internal resistance or current amount of the first, second, and third unit cells 1, 2, and 3. Relatively, when the internal resistance is small or the current amount is large, the speed of the temperature increase is fast. Also, relatively, when the internal resistance is large or the current amount is small, the speed of the temperature increase is slow.

The first, second, and third unit cells 1, 2, and 3 have the same structure. They, however, have different internal resistances or different current amounts. The relative speed of the temperature increase of the first, second, and third unit cells 1, 2, and 3 may be predicted by measuring the internal resistance and the voltage-current amount of the first, second, and third unit cells 1, 2, and 3.

The unit cells are classified into 2 to 3 grades according to the internal resistances or the current amounts. Accordingly, the temperature sensor 5 may be installed to a unit cell having a small internal resistance, and the temperature sensor 5 may be installed to a unit cell having a large current amount.

Regarding to the installation of the temperature sensor 5, the temperature sensor 5 may contacts the outer surface of the can 20 of the first unit cell 1, and the temperature sensor 5 may also be formed as a thermistor of which an electrical resistance is changed according to the temperature of the first unit cell 1. The first unit cell 1 attached with the temperature sensor 5 has the fastest speed of the temperature increase than the second and third unit cell 2, and 3. That is to say, the first unit cell 1 installed with the temperature sensor 5 has the lowest internal resistance or the largest output current amount among the first, the second and third unit cells 1, 2 and 3.

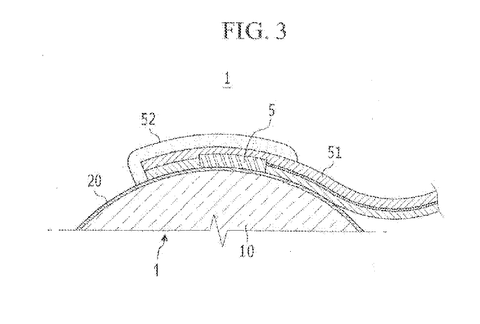

FIG. 3 is part of a cross-sectional view taken along line III-III′ of FIG. 1. As shown in FIG. 3, the temperature sensor 5 is curved and attached to the curved surface of the can 20 of the cylindrical rechargeable battery of the unit cell 1. Accordingly, the temperature sensor 5 forms a wide contact surface on the can 20. Therefore, the temperature of the outer surface of the first unit cell 1 may be effectively detected. The temperature sensor 5 is electrically connected to the protection circuit module 4 through a flexible printed circuit (FPC) 51. For example, the temperature sensor 5 may maintain the attachment state to the curved surface of the can 20 by an adhesive tape or a silicone adhesive.

The protection circuit module 4 controls the cell pack 6 based on the temperature of the first unit cell 1, and the temperature of the first unit cell 1 is sensed by the temperature sensor 5. Although the second and third unit cells 2 and 3 are thermally maintained in a stable state, the cell pack 6 is controlled based on the temperature of the first unit cell 1, which has the fastest speed of temperature increase. Accordingly, the first, second, and third unit cells 1, 2, and 3 may be protected from the increase of their temperatures.

Again, as shown in FIG. 1 and FIG. 2, the temperature sensor 5 may be attached to the side of the anode terminal near the anode collecting plate 11d in the first unit cell 1. The current flows through the positive temperature coefficient element 35 even when the resistance of the positive temperature coefficient element 35 increases due to the increase of the inner temperature. Accordingly, the inner temperature is continuously increased toward the positive temperature coefficient element 35. That is to say, in the first unit cell 1, the speed of the temperature increase in the side of the anode terminal is larger than the side of the cathode terminal near the cathode collecting plate 13d.

Also, during the overcharge, oxygen is generated in the active material of the coated portion 11a of the anode 11 of the electrode assembly 10. The oxygen reacts with the electrolyte solution, thereby heat is generated in the first unit cell 1. Accordingly, the temperature is firstly increased in the coated portion 11a of the anode 11, and then the temperature of the anode collecting plate 11d connected to the anode 11 is increased.

Accordingly, in the first exemplary embodiment, the temperature sensor 5 is attached to the side of the anode terminal near the anode collecting plate 11d in the first unit cell 1 such that the cell pack 6 is controlled based on the temperature of the portion such as the first unit cell 1, which has the fastest speed of the temperature increase, and thereby the cell pack 6 may be further effectively protected.

Hereinafter, a second exemplary embodiment is described. The description of the same configurations in the second exemplary embodiment is omitted and different components are contrasted and described comparing with the first exemplary embodiment.

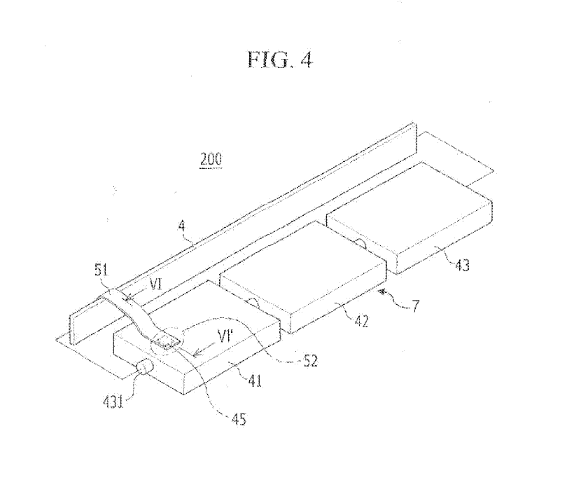

FIG. 4 is a perspective view of a rechargeable battery pack constructed as a second exemplary embodiment of present invention. As shown in FIG. 4, a rechargeable battery pack 200 includes a cell pack 7. The cell pack 7 includes first, second, and third unit cells 41, 42, and 43. The first, second, and third unit cells 41, 42, and 43 are connected in series. Each of the first, second, and third unit cells 41, 42, and 43 is made of a rechargeable battery. A protection circuit module 4 (PCM) is connected to a terminal of the cell pack 4 and electrically protects the cell pack 7. A temperature sensor 45 is attached to the first unit cell 41 and is electrically connected to the protection circuit module 4.

In the rechargeable battery pack 100 of the first exemplary embodiment, the first, second, and third unit cells 1, 2, and 3 are formed as cylindrical rechargeable batteries, while in the rechargeable battery pack 200 of the second exemplary embodiment, first, second, and third unit cells 41, 42, and 43 are formed as angular rechargeable batteries.

In the first, second, and third unit cells 1, 2, and 3 of the cylindrical rechargeable batteries, the positive temperature coefficient element 35 is provided at the side of the anode terminal such that the current is controlled by the inner temperature. Compared with this, the first, second, and third unit cells 41, 42, and 43 of the angular rechargeable batteries do not include the configuration that the current is controlled by the inner temperature.

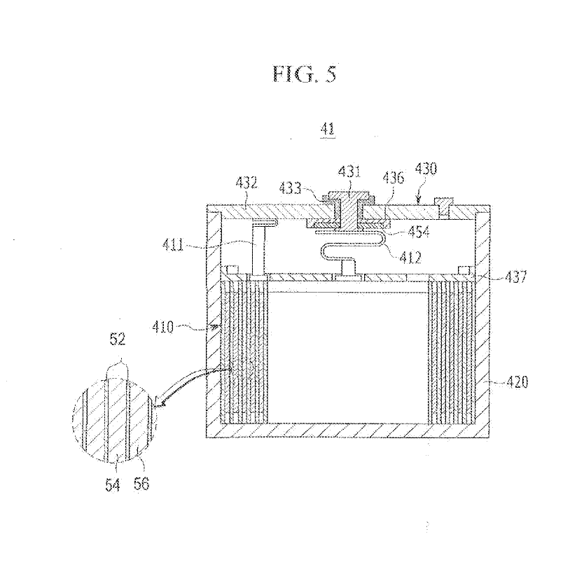

FIG. 5 is a cross-sectional view of unit cell 41 (i.e. a rechargeable battery) applied to the rechargeable battery pack of FIG. 4. The first, second, and third unit cells 41, 42, and 43 formed with the angular rechargeable batteries have the same structure, so for convenience the angular rechargeable battery is described as the first unit cell 41 in FIG. 5. As shown in FIG. 5, the first unit cell 41 includes an electrode assembly 410, a can 420, and a cap assembly 430. The can 420 encompasses the electrode assembly 410. The electrode assembly 410 has an anode 54, a cathode 56 and a separator 52. The separator 52 is disposed between the anode 54 and the cathode 56 with an electrolyte solution. The cap assembly 430 seals opening of the can 420.

The can 420 receives the electrode assembly 410 through the opening formed on one side, and is formed with a conductor to have the role of the electrode terminal. For example, the can 420 is electrically connected to the anode 54 44 of the electrode assembly 410, thereby the can 420 functions as an anode terminal. An electrode terminal 431 of the cap assembly 430 is electrically connected to the cathode 56 of the electrode assembly 410, thereby the electrode terminal 431 functions as a cathode terminal.

The cap assembly 430 includes a cap plate 432, an electrode terminal 431, a terminal plate 454, an insulating plate 436, and an insulating case 437. The cap plate 432 is fixed to the opening of the can 420. The electrode terminal 431 is inserted into a terminal hole of the cap plate 432 with an insulating gasket 433 interposed therebetween. The terminal plate 454 is electrically connected to the lower portion of the electrode terminal 431. The insulating plate 436 is disposed between the cap plate 432 and the terminal plate 454. The insulating case 437 separates the electrode assembly 410 from the cap assembly 430. The insulating gasket 433 electrically insulates the electrode terminal 431 from the cap plate 432, and the insulating plate 436 electrically insulates the terminal plate 454 from the cap plate 432.

An anode lead tab 411 is fixed to the anode 54 of the electrode assembly 410, and is welded to the inner surface of the cap plate 432, and thereby the current of the anode 54 is transmitted to the cap plate 432 and the can 420. That is, the can 420 functions as the anode terminal. A cathode lead tab 412 is fixed to the cathode 56 of the electrode assembly 410, and is welded to the lower surface of the terminal plate 454, and thereby the current of the cathode 56 is transmitted to the terminal plate 454 and the electrode terminal 431. That is, the electrode terminal 431 functions as the cathode terminal. In the second exemplary embodiment, the anode lead tab 411 and the cathode lead tab 412 are drawn out in the same direction, but the anode lead tab 411 and the cathode lead tab 412 may be drawn out in opposite directions (not shown in Figures).

Again as shown in FIG. 4, in the rechargeable battery pack 200 according to the second exemplary embodiment, the cell pack 7 is formed with the first, second, and third unit cells 41, 42, and 43 of the angular rechargeable batteries, and the a temperature sensor 45 is attached to the first unit cell 41, which has the fastest speed of the temperature increase, thereby the temperature sensor 45 protects the cell pack 7 from the increase in temperature.

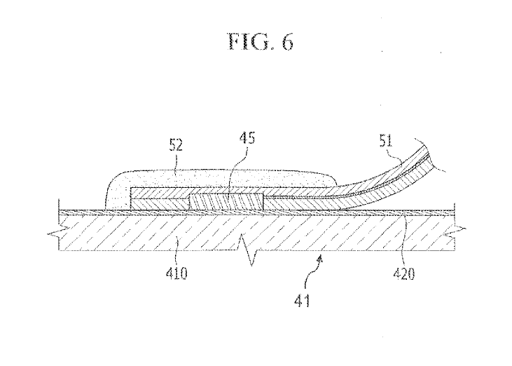

FIG. 6 is part of a cross-sectional view taken along line VI-VI′ of FIG. 4. As shown in FIG. 6, the temperature sensor 45 is attached to the flat surface of the can 420 of the angular rechargeable battery of the first unit cell 41. Accordingly, the temperature sensor 45 forms a wide contact surface on the can 420. Therefore, the temperature of the outer surface of the first unit cell 41 may be effectively detected. The temperature sensor 45 is electrically connected to the protection circuit module 4 through the flexible printed circuit (FPC) 51. For example, the temperature sensor 45 may maintain the attachment state to the flat surface of the can 420 by a sealing member 52. The sealing member 52 may be tape or silicone.

In the rechargeable battery pack 100 of the first exemplary embodiment, the temperature sensor 5 is installed to the cylindrical rechargeable battery of the first unit cell 1 and connected to the protection circuit module 4, while in the rechargeable battery pack 200 of the second exemplary embodiment, the temperature sensor 45 is installed to the angular rechargeable battery of the first unit cell 41 and connected to the protection circuit module 4.

Also, the protection circuit module and the temperature sensor may be applied to a rechargeable battery pack including rechargeable batteries (for example, a lithium ion polymer rechargeable batteries) having a flat plate shape (not shown in Figures). That is, the lithium ion polymer rechargeable battery forms the unit cells, and includes an electrode assembly and a flat exterior member enclosing the electrode assembly. The electrode assembly includes an anode and a cathode and a polymer solid electrolyte film, and the polymer solid electrolyte film is interposed between the anode and the cathode for passing lithium ions. The temperature sensor may be attached to the flat exterior member.

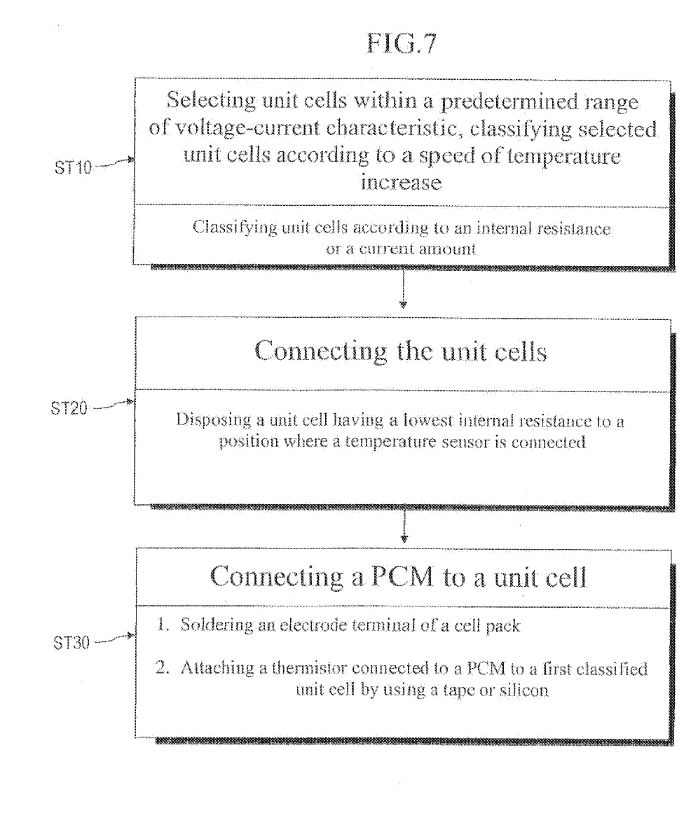

FIG. 7 is a flowchart illustrating a method for manufacturing a rechargeable battery pack constructed as an exemplary embodiment of present invention. Referring to the first exemplary embodiment of FIG. 1 and FIG. 7, a method for manufacturing the rechargeable battery pack 100 includes a classifying step ST10, a cell packing step ST20, and a connecting step ST30 of a protection, circuit module.

The classifying step ST10 classifies the first, second, and third unit cells 1, 2, and 3 according to the speed of their inner temperature increase, and the first, second, and third unit cells 1, 2, and 3 are made of rechargeable batteries.

For example, the classifying step ST10 may classify the first, second, and third unit cells 1, 2, and 3 by measuring the internal resistance or the output current amount of the first, second, and third unit cells 1, 2, and 3.

For example, the classifying step ST10 classifies and ascertains the first unit cell 1 having the lowest internal resistance or the largest current amount among the first, second, and third unit cells 1, 2, and 3.

If voltage-current characteristic difference is large among the first, second, and third unit cells 1, 2, and 3, deterioration of balance in the unit cells 1, 2, and 3 of the cell pack 6 may be generated.

Accordingly, the classifying step ST10 selects three unit cells from other unit cells within a predetermined range of the voltage-current characteristic as the first, second, and third unit cells 1, 2, and 3 of the cell pack 6 in the first exemplary embodiment. The rechargeable battery pack 100 may be manufactured with the selected first, second, and third unit cells 1, 2, and 3.

The cell packing step ST20 disposes the first unit cell 1 at a position where the temperature sensor 5 is connected firstly, and then electrically connects the classified first, second, and third unit cells 1, 2, and 3 to complete the cell pack 6. As stated in the classifying step ST10, the first unit cell 1 is a unit cell having the faster speed of the temperature increase caused by the internal resistance or the current amount of the unit cell comparing with the other two selected unit cells 2 and 3. The temperature sensor 5 is electrically connected to the protection circuit module 4 through the flexible printed circuit (FPC) 51, and is connected to the cell pack 6. Accordingly, the first unit cell 1 is disposed at the position where the temperature sensor 5 is attached.

The connecting step ST30 connects the protection circuit module 4 to the cell pack 6. That is, the connecting step ST30 installs and disposes the temperature sensor 5 to the classified and selected first unit cell 1, which has the fastest speed of the temperature increase among the selected unit cells 1, 2, and 3, and connects the protection circuit module 4 by soldering the terminal of the cell pack 6 to the protection circuit module 4.

While the foregoing paragraphs describe the details in connection with what is presently considered to be practical exemplary embodiments, it is to be understood that the principle of the present invention is not limited to the described embodiments. On the contrary, described embodiments are intended to cover various modifications and equivalent arrangements included within the spirit and scope of the appended claims.

What is claimed is:

1. A rechargeable battery pack, comprising:
a cell pack comprising unit cells formed with rechargeable batteries;
a protection circuit module controlling the cell pack; and
a temperature sensor attached to a unit cell having the fastest speed of temperature increase among the unit cells, and electrically connected to the protection circuit module.

2. The rechargeable battery pack of claim 1, wherein
the temperature sensor is formed with a thermistor.

3. The rechargeable battery pack of claim 1, wherein
the temperature sensor is attached to a unit cell having the lowest internal resistance among the unit cells.

4. The rechargeable battery pack of claim 1, wherein
the temperature sensor is attached to a unit cell having the largest output current amount among the unit cells.

5. The rechargeable battery pack of claim 1, wherein
the temperature sensor is attached to one side of anode terminal in a unit cell having the fastest speed of temperature increase.

6. The rechargeable battery pack of claim 1, wherein
the unit cells are formed of either cylindrical rechargeable batteries or angular rechargeable batteries.

7. The rechargeable battery pack of claim 6, wherein
the temperature sensor is attached to a curved surface of a can of a cylindrical rechargeable battery.

8. The rechargeable battery pack of claim 6, wherein
the temperature sensor is attached to a flat surface a can of an angular rechargeable battery.

9. A method for manufacturing a rechargeable battery pack, comprising:
a classifying step comprising selecting unit cells within a predetermined range of voltage-current characteristic and classifying unit cells according to a speed of temperature increase, and the unit cells are form of rechargeable batteries;
a cell packing step for connecting the unit cells, disposing a unit cell having the fastest speed of temperature increase to a position where a temperature sensor is connected and then electrically connecting the classified unit cells to form a cell pack; and
a connecting step for installing a protection circuit module to a position where the temperature sensor is connected and then connecting the temperature sensor with the unit cell having the fastest speed of temperature increase in a terminal of the cell pack and the protection circuit module with the temperature sensor.

10. The method for manufacturing a rechargeable battery pack of claim 9, wherein,
the classifying step classifies the unit cells according to internal resistances.

11. The method for manufacturing a rechargeable battery pack of claim 9, wherein,
the classifying step classifies the unit cells according to output current amounts.

12. The method for manufacturing a rechargeable battery pack of claim 1, wherein,
the connecting step attaches the temperature sensor to a side of anode terminal of the unit cell having the fastest speed of temperature increase.
